(19) United States
(12) Patent Application Publication
(10) Pub. No.: US 2016/0373148 A1
(43) Pub. Date: Dec. 22, 2016

(54) SATELLITE RECEIVER AND SIGNAL RECEIVING CIRCUIT THEREOF

(71) Applicant: MAXTEK TECHNOLOGY CO., LTD., Taipei (TW)

(72) Inventors: Ke-Kung LIAO, Taipei (TW); Pei-Lu WU, Taipei (TW)

(21) Appl. No.: 15/139,705

(22) Filed: Apr. 27, 2016

(30) Foreign Application Priority Data
Jun. 18, 2015 (TW) 104119831

(51) Int. Cl. H04B 1/16; H03F 1/26; H03F 3/21; H04B 1/10; H02M 3/07

(52) U.S. Cl. CPC H04B 1/16; H04B 1/10; H02M 3/07; H03F 3/211; H03F 1/26; H03F 2203/21157; H03F 2200/168; H03F 2200/294; H03F 2200/408

(57) ABSTRACT

A signal receiving circuit of a satellite receiver is disclosed. The satellite receiver comprises at least a first antenna and the signal receiving circuit is adapted to be electrically connected with a digital signal converting device. The signal receiving circuit comprises an amplifier module and a signal processing and power supply unit. The amplifier module is electrically connected with at least a first antenna to receive an antenna signal. The signal processing and power supply unit is electrically connected with the amplifier module to down convert the antenna signal and transmit the antenna signal to the digital signal converting device. The signal processing and power supply unit comprises a charge pump, which receives the output signal of the digital signal converting device and provides at least a driving power for the signal receiving circuit.

### CROSS REFERENCE TO RELATED APPLICATIONS

This Non-provisional application claims priority under 35 U.S.C. §119(a) on Patent Application No(s). 104119831 filed in Taiwan, Republic of China on Jun. 18, 2015, the entire contents of which are hereby incorporated by reference.

### BACKGROUND OF THE INVENTION

Field of Invention

This invention relates to a signal receiving circuit of a satellite receiver and, in particular, to a signal receiving circuit of a satellite receiver capable of supplying power.

Related Art

Recently, electronic products are developed into products with low power consumption and high conversion efficiency. They can not only reduce the required energy but also utilize the energy more effectively.

The conventional satellite receiver usually uses a linear dropout regulator (LDO) as the voltage source. Because the external voltage source received by the satellite receiver is usually 13V˜18V, the input voltage of the linear dropout regulator is also 13V˜18V. However, if the linear dropout regulator needs to convert the output voltage into 5V, this conversion efficiency is poor. For example, assuming that the input voltage is 13V, the output voltage is 5V and the current is 0.1 A (for the linear dropout regulator, the input current is identical with the output current), it could be found that the input power is 1.3 W (13V*0.1 A), the output power is 0.5 W (5V*0.1 A), the conversion efficiency is 38.4% (0.5 W/1.3 W*100%) and the power loss is even up to 0.8 W. Assuming that the input voltage is 18V and the output voltage is 5V, it could be found that the input power is 1.8W (18V*0.1A), the output power is 0.5 W (5V*0.1 A), the conversion efficiency is 27.7% (0.5 W/1.8 W*100%) and the power loss badly becomes 1.3 W. In addition to deplorable conversion efficiency, the generated heat is greatly increased so as to need the corresponding heat dissipating design.

Therefore, it is an important subject to provide a signal receiving circuit of a satellite receiver capable of supplying power with high conversion efficiency.

### SUMMARY OF THE INVENTION

In view of the foregoing subject, an objective of this invention is to provide a signal receiving circuit of a satellite receiver. The satellite receiver comprises at least a first antenna and the signal receiving circuit is adapted to be electrically connected with a digital signal converting device. The signal receiving circuit comprises an amplifier module and a signal processing and power supply unit. The amplifier module is electrically connected with at least a first antenna to receive an antenna signal. The signal processing and power supply unit is electrically connected with the amplifier module to down convert the antenna signal and transmit the antenna signal to the digital signal converting device. The signal processing and power supply unit comprises a charge pump, which receives the output signal of the digital signal converting device and provides at least a driving power for the signal receiving circuit.

In one embodiment, the satellite receiver further comprises at least a second antenna.

In one embodiment, the amplifier module comprises a first amplifier, a second amplifier and a third amplifier. The first amplifier receives the antenna signal of the first antenna. The second amplifier receives the antenna signal of the second antenna. The third amplifier is electrically connected with the first amplifier and the second amplifier and receives the antenna signal of the first amplifier or the second amplifier.

In one embodiment, each of the first amplifier, the second amplifier and the third amplifier is a low-noise amplifier (LNA).

In one embodiment, the signal processing and power supply unit further comprises a band-pass filter, an oscillator, a mixer and a fourth amplifier. The band-pass filter receives the antenna signal of the amplifier module, filters out the noise and acquires the signal at a proper frequency. The oscillator provides an oscillation signal. The mixer receives the oscillation signal and down converts the antenna signal. The fourth amplifier amplifies the down converted antenna signal and transmits the amplified antenna signal to the digital signal converting device.

In one embodiment, the fourth amplifier is an intermediate frequency amplifier (IFA).

In one embodiment, the frequency of the oscillation signal is 9.75 GHz˜10.6 GHz.

In one embodiment, the charge pump includes a first capacitance, an output capacitance, a first switch, a second switch, a third switch and a fourth switch. The first capacitance includes a first end a second end. The output capacitance includes a first end and a second end, and the second end of the output capacitance is electrically connected with a ground end. The first switch includes a first end and a second end, and the first end and the second end of the first switch are respectively electrically connected with a working power and the first end of the first capacitance. The second switch includes a first end and a second end, the first end of the second switch is electrically connected with a ground end, and the second end of the second switch is electrically connected with the second end of the first capacitance. The third switch includes a first end and a second end, and the first end of the third switch is electrically connected with the second end of the first switch and the first end of the first capacitance. The fourth switch includes a first end and a second end, and the first end of the fourth switch is electrically connected with the second end of the second switch and the second end of the first capacitance. The second end of the third switch is electrically connected with the second end of the fourth switch and the first end of the output capacitance. In the first operation stage, the first switch and the fourth switch are short-circuited and the second switch and the third switch are open-circuited. In the second operation stage, the first switch and the fourth switch are open-circuited and the second switch and the third switch are short-circuited. An output voltage is outputted from the first end of the output capacitance.

In view of the foregoing subject, an objective of this invention is to provide a satellite receiver which is adapted to be electrically connected with a digital signal converting device. The satellite receiver includes at least a first antenna and a signal receiving circuit. The signal receiving circuit comprises an amplifier module and a signal processing and power supply unit. The amplifier module is electrically connected with at least a first antenna to receive an antenna signal. The signal processing and power supply unit is electrically connected with the amplifier module to down convert the antenna signal and transmit the antenna signal to the digital signal converting device. The signal processing and power supply unit comprises a charge pump, which receives the output signal of the digital signal converting device and provides at least a driving power for the signal receiving circuit.

In one embodiment, the satellite receiver further comprises at least a second antenna.

In one embodiment, the amplifier module comprises a first amplifier, a second amplifier and a third amplifier. The first amplifier receives the antenna signal of the first antenna. The second amplifier receives the antenna signal of the second antenna. The third amplifier is electrically connected with the first amplifier and the second amplifier and receives the antenna signal of the first amplifier or the second amplifier.

In one embodiment, each of the first amplifier, the second amplifier and the third amplifier is a low-noise amplifier (LNA).

In one embodiment, the signal processing and power supply unit further comprises a band-pass filter, an oscillator, a mixer and a fourth amplifier. The band-pass filter receives the antenna signal of the amplifier module, filters out the noise and acquires the signal at a proper frequency. The oscillator provides an oscillation signal. The mixer receives the oscillation signal and down converts the antenna signal. The fourth amplifier amplifies the down converted antenna signal and transmits the amplified antenna signal to the digital signal converting device.

In one embodiment, the fourth amplifier is an intermediate frequency amplifier (IFA).

In one embodiment, the frequency of the oscillation signal is 9.75 GHz˜10.6 GHz.

In one embodiment, the charge pump includes a first capacitance, an output capacitance, a first switch, a second switch, a third switch and a fourth switch. The first capacitance includes a first end a second end. The output capacitance includes a first end and a second end, and the second end of the output capacitance is electrically connected with a ground end. The first switch includes a first end and a second end, and the first end and the second end of the first switch are respectively electrically connected with a working power and the first end of the first capacitance. The second switch includes a first end and a second end, the first end of the second switch is electrically connected with a ground end, and the second end of the second switch is electrically connected with the second end of the first capacitance. The third switch includes a first end and a second end, and the first end of the third switch is electrically connected with the second end of the first switch and the first end of the first capacitance. The fourth switch includes a first end and a second end, and the first end of the fourth switch is electrically connected with the second end of the second switch and the second end of the first capacitance. The second end of the third switch is electrically connected with the second end of the fourth switch and the first end of the output capacitance. In the first operation stage, the first switch and the fourth switch are short-circuited and the second switch and the third switch are open-circuited. In the second operation stage, the first switch and the fourth switch are open-circuited and the second switch and the third switch are short-circuited. An output voltage is outputted from the first end of the output capacitance.

As mentioned above, in the satellite receiver of this invention, the charge pump is integrated into the signal processing and power supply unit, so that the complexity of the circuit design can be reduced and the conversion efficiency of the charge pump can be enhanced, in comparison with the conversion efficiency (about 20%-40%) of the conventional LDO. Therefore, the power loss and the cost of the heat dissipation can be effectively reduced.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic diagram of a signal receiving circuit of a satellite receiver of an embodiment of the invention;

FIG. 2A is a schematic diagram of the circuit of the charge pump in FIG. 1;

FIG. 2B is a schematic diagram of the charge pump of FIG. 2A at the first operation stage; and

FIG. 2C is a schematic diagram of the charge pump of FIG. 2A at the second operation stage.

### DETAILED DESCRIPTION OF THE INVENTION

The present invention will be apparent from the following detailed description, which proceeds with reference to the accompanying drawings, wherein the same references relate to the same elements.

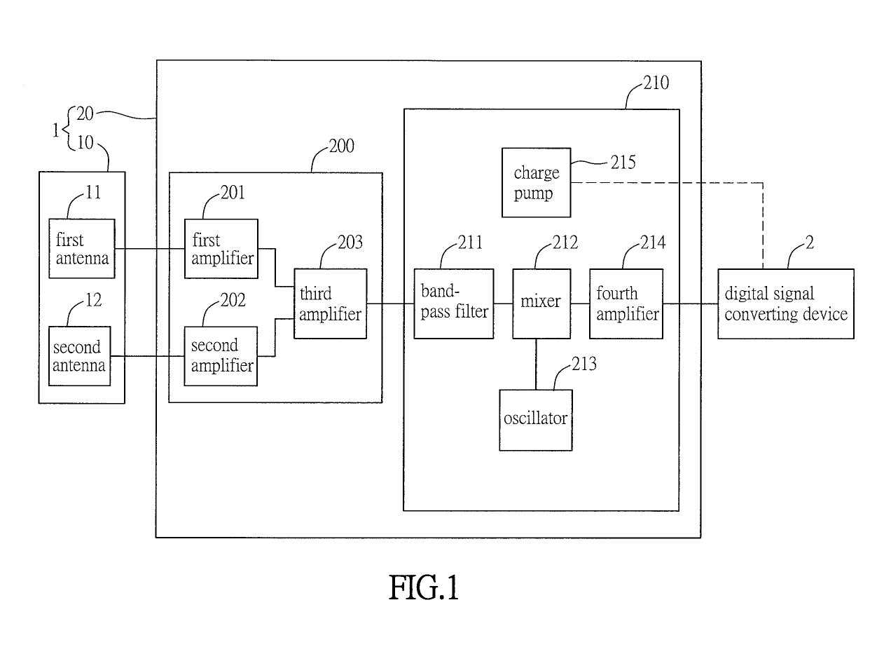

As shown in FIG. 1, the satellite receiver 1 includes an antenna module 10 and a signal receiving circuit 20. The satellite receiver 1 is electrically connected with a digital signal converting device 2 to transmit the received antenna signal to the digital signal converting device 2 for displaying.

The satellite receiver 1 is disposed on a parabolic antenna (not shown) to receive the antenna signal. The antenna module 10 at least includes at least a first antenna 11. In a favorable embodiment, the antenna module 10 further includes at least a second antenna 12, and the first antenna 11 and the second antenna 12 respectively receive the antenna signals in the horizontal direction and the vertical direction.

The signal receiving circuit 20 includes an amplifier module 200 and a signal processing and power supply unit 210. The amplifier module 200 includes a first amplifier 201, a second amplifier 202 and a third amplifier 203. The first amplifier 201 and the second amplifier 202 are electrically connected with the first antenna 11 and the second antenna 12, respectively, to amplify the antenna signals received by the first antenna 11 and the second antenna 12. The third amplifier 203 is electrically connected with the first amplifier 201 and the second amplifier 202 to amplify again the antenna signals which have been amplified by the first amplifier 201 and the second amplifier 202.

After being amplified by the first amplifier 201, the second amplifier 202 and the third amplifier 203 of the amplifier module 200, the antenna signal received by the first antenna 11 or the second antenna 12 is transmitted to the signal processing and power supply unit 210. Each of the first amplifier 201, the second amplifier 202 and the third amplifier 203 is a low-noise amplifier (LNA).

The signal processing and power supply unit 210 includes a band-pass filter 211, a mixer 212, an oscillator 213, a fourth amplifier 214 and a charge pump 215.

The amplified antenna signal is transmitted to the band-pass filter 211 to filter out and acquire the signal at the required frequency band. The filtered antenna signal is transmitted to the mixer 212, and the mixer 212 uses the oscillation signal of 9.75 GHz˜10.6 GHz provided by the oscillator 213 to down convert the antenna signal of which the frequency is originally at 10.7 GHz˜12.75 GH. Then, the down converted antenna signal is transmitted to the fourth amplifier 214 for the signal amplification and then transmitted to the digital signal converting device 2 for displaying. The fourth amplifier 214 is an intermediate frequency amplifier (IFA).

The charge pump 215 is disposed in the signal processing and power supply unit 210. It receives the output signal (about 13V˜18V) of the digital signal converting device 2 and converts the output signal into a stable driving power (5V-7V) which is provided for the signal receiving circuit 20.

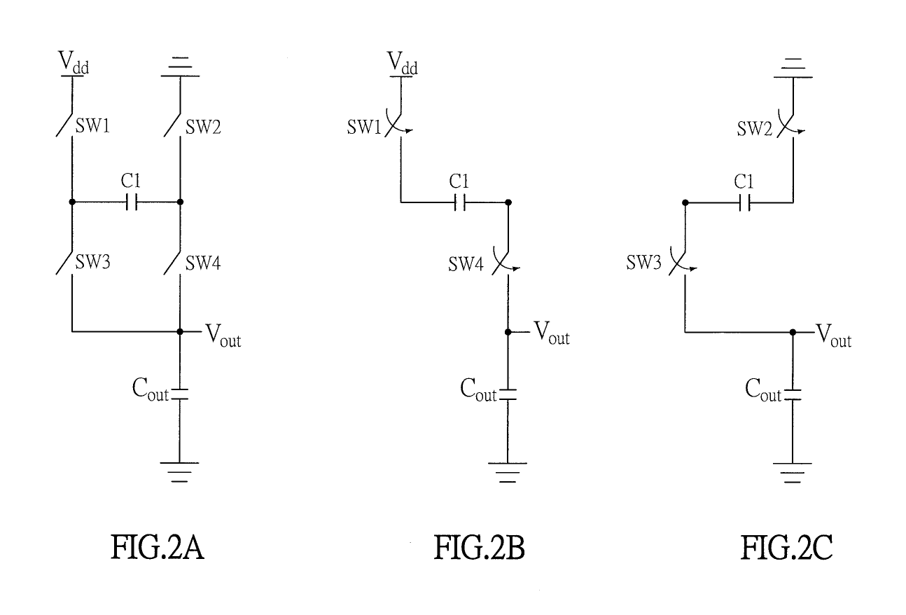

Refer to FIGS. 2A to 2C, wherein FIG. 2A is a schematic diagram of the circuit of the charge pump in FIG. 1, FIG. 2B is a schematic diagram of the charge pump of FIG. 2A at the first operation stage, and FIG. 2C is a schematic diagram of the charge pump of FIG. 2A at the second operation stage. In this embodiment, the charge pump 215 includes a first capacitance C1, an output capacitance Cₒᵤₜ, a first switch SW1, a second switch SW2, a third switch SW3 and a fourth switch SW4. For the convenient illustration, in the following description, the upper end of each of the switches and the output capacitance Cₒᵤₜ is the first end, and the lower end thereof is the second end. Since the first capacitance C1 is disposed transversely in the figures, the left end thereof is the first end and the right end thereof is the second end, which will not be explained again in the below.

The first end of the first switch SW1 is electrically connected with a working power V_{dd}, the second end of the first switch SW1 is electrically connected with the first end of the third switch SW3 and the first end of the first capacitance C1. The first end of the second switch SW2 is electrically connected with a ground end, and the second end of the second switch SW2 is electrically connected with the second end of the first capacitance C1 and the first end of the fourth switch SW4. The second end of the third switch SW3 is electrically connected with the second end of the fourth switch SW4 and the first end of the output capacitance Cₒᵤₜ. The second end of the output capacitance Cₒᵤₜ is electrically connected with a ground end. The first end of the output capacitance Cₒᵤₜ is used as the output end of the charge pump 215 outputting an output voltage Vₒᵤₜ.

Because the charge pump 215 is a switch-type power converter, the first switch SW1 and the fourth switch SW4 operate simultaneously and the second switch SW2 and the third switch SW3 operate simultaneously.

In the first operation stage of the charge pump 215, the first switch SW1 and the fourth switch SW4 are short-circuited, and the second switch SW2 and the third switch SW3 are open-circuited. In the second operation stage of the charge pump 215, the first switch SW1 and the fourth switch SW4 are open-circuited, and the second switch SW2 and the third switch SW3 are short-circuited.

The amount of the electric charge stored in the first capacitance C1 in the first operation stage is equal to that stored in the first capacitance C1 in the second operation stage. Therefore, according to the formula: Q=C*V (the amount of the electric charge=capacitance value*voltage value), the amount of the electric charge stored in the first capacitance C1 in the first operation stage is (V_{dd}−Vₒᵤₜ)*C1, and the amount of the electric charge stored in the first capacitance C1 in the second operation stage is Vₒᵤₜ*C1. The amounts of the electric charge stored in the first capacitance C1 in the first and second operation stages are equal to each other, so (V_{dd}-Vₒᵤₜ)*C1=Vₒᵤₜ*C1, and the output voltage Vₒᵤₜ=1/2*V_{dd} can be derived therefrom.

Therefore, the charge pump 215 can provide a stable output voltage Vₒᵤₜ for the signal receiving circuit 20 by the interaction of the first switch SW1, the second switch SW2, the third switch SW3 and the fourth switch SW4 in the first and second operation stages. Besides, the charge pump used in this invention can further output the required current according to the loading, not like the conventional art where the linear dropout regulator have the same input current and output current. For example, when the input voltage is 18V, the input current 0.06 mA, the output voltage is 9V and the output current is 0.1 A (the output current is fixed to drive other components), the conversion efficiency is 83.33% ([(9*0.1)/(18*0.06)]*100%); when the input voltage is 13V, the input current 0.06 mA, the output voltage is 6.5V and the output current is 0.1 A, the conversion efficiency is 83.3% ([(6.5*0.1)/(13*0.06)]*100%). Moreover, the circuit structure of the charge pump 215 of this embodiment is just for example, and another kind of the circuit structure of the charge pump may be used.

Summarily, in the satellite receiver of this invention, the charge pump is integrated into the signal processing and power supply unit, so that the complexity of the circuit design can be reduced and the conversion efficiency of the charge pump can be enhanced, in comparison with the conversion efficiency (about 20%˜40%) of the conventional MO. Therefore, the power loss and the cost of the heat dissipation can be effectively reduced.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

1. A signal receiving circuit of a satellite receiver, wherein the satellite receiver comprises at least a first antenna and the signal receiving circuit is adapted to be electrically connected with a digital signal converting device, comprising:
an amplifier module electrically connected with at least a first antenna to receive an antenna signal; and
a signal processing unit electrically connected with the amplifier module to down converts the antenna signal and transmit the antenna signal to the digital signal converting device; and
a power supply unit comprising:
a charge pump receiving the output signal of the digital signal converting device and providing at least a driving power for the signal receiving circuit.

2. The signal receiving circuit recited in claim 1, wherein the satellite receiver further comprises at least a second antenna.

3. The signal receiving circuit recited in claim 2, wherein the amplifier module comprises:
a first amplifier receiving the antenna signal of the first antenna;
a second amplifier receiving the antenna signal of the second antenna; and
a third amplifier electrically connected with the first amplifier and the second amplifier and receiving the antenna signal of the first amplifier or the second amplifier.

4. The signal receiving circuit recited in claim 3, wherein each of the first amplifier, the second amplifier and the third amplifier is a low-noise amplifier (LNA).

5. The signal receiving circuit recited in claim 1, wherein the signal processing unit comprises:
a band-pass filter receiving the antenna signal of the amplifier module, filtering out the noise and acquiring the signal at a proper frequency;
an oscillator providing an oscillation signal;
a mixer receiving the oscillation signal and down converting the antenna signal; and
a fourth amplifier amplifying the down converted antenna signal and transmitting the amplified antenna signal to the digital signal converting device.

6. A satellite receiver adapted to be electrically connected with a digital signal converting device, comprising:
at least a first antenna; and
a signal receiving circuit, comprising:
an amplifier module electrically connected with at least a first antenna to receive an antenna signal;
a signal processing unit electrically connected with the amplifier module to down convert the antenna signal and transmit the antenna signal to the digital signal converting device; and
a power supply unit comprising:
a charge pump receiving the output signal of the digital signal converting device and providing at least a driving power for the signal receiving circuit.

7. The satellite receiver recited in claim 6, further comprising at least a second antenna.

8. The satellite receiver recited in claim 7, wherein the amplifier module comprises:
a first amplifier receiving the antenna signal of the first antenna;
a second amplifier receiving the antenna signal of the second antenna; and
a third amplifier electrically connected with the first amplifier and the second amplifier and receiving the antenna signal of the first amplifier or the second amplifier.

9. The satellite receiver recited in claim 8, wherein each of the first amplifier, the second amplifier and the third amplifier is a low-noise amplifier (LNA).

10. The satellite receiver recited in claim 6, wherein the signal processing unit further comprises:
a band-pass filter receiving the antenna signal of the amplifier module, filtering out the noise and acquiring the signal at a proper frequency;
an oscillator providing an oscillation signal;
a mixer receiving the oscillation signal and down converting the antenna signal; and
a fourth amplifier amplifying the down converted antenna signal and transmitting the amplified antenna signal to the digital signal converting device.

11. The signal receiving circuit recited in claim 1, wherein the charge pump is a capacitive charge pump.

12. The satellite receiver recited in claim 6, wherein the charge pump is a capacitive charge pump.
